(19) United States
(12) Patent Application Publication
(10) Pub. No.: US 2018/0163290 A1
(43) Pub. Date: Jun. 14, 2018

(54) MASK DEVICE, VAPOR DEPOSITION DEVICE AND METHOD FOR PREPARING MASK DEVICE

(71) Applicant: SHANGHAI TIANMA MICRO-ELECTRONICS CO., LTD., Shanghai (CN)

(72) Inventors: Jian XU, Shanghai (CN); Yaoyang LIU, Shanghai (CN)

(73) Assignee: SHANGHAI TIANMA MICRO-ELECTRONICS CO., LTD., Shanghai (CN)

(21) Appl. No.: 15/880,532

(22) Filed: Jan. 26, 2018

(30) Foreign Application Priority Data
Sep. 29, 2017 (CN) 201710908524.4

(51) Int. Cl. C23C 14/04; H01L 51/56; C25D 1/10

(52) U.S. Cl. CPC C23C 14/042; H01L 51/001; C25D 1/10; H01L 51/56

(57) ABSTRACT

The present disclosure provides a mask device, a vapor deposition device and a method for preparing a mask device, related to the vapor deposition field, for improving the lamination fit between a substrate to be vapor-deposited and a mask and the effect of vapor deposition. The mask device includes a mask made of a ferromagnetic material and the mask includes at least one deposition area and at least one non-deposition area; deposition through-holes is defined in the deposition area, and the non-deposition area includes a transition area adjacent to the deposition area, transition holes each having a volume less than the volume of the deposition through-hole are defined in the transition area, and the volume of the transition holes gradually decreases in a direction from the deposition area to the non-deposition area. The mask device is adapted to be used in the vapor deposition device.

### CROSS-REFERENCE TO RELATED DISCLOSURES

The present disclosure claims priority to Chinese Patent Disclosure No. 201710908524.4, filed on Sep. 29, 2017, the content of which is incorporated herein by reference in its entirety.

### TECHNICAL FIELD

The present disclosure relates to the technical field of vapor deposition and, particularly, relates to a mask device, a vapor deposition device and a method for preparing the mask device.

### BACKGROUND

Among human sensory organs, visual organs(eyes) receive the most information. In the industry production and life, more and more versatile visual information is required. Therefore, the display technology plays a pivotal role in today's human society. Since its inception, the display technology has been developed rapidly. With the development of society and people's continuous demands on material condition, the present display technology advances rapidly in high contrast, high resolution, full color display, low energy consumption, high reliability, long service life, small thickness as well as light weight.

Organic light-emitting diode (OLED) has become a strong competitor of LCD panel and is called as the next generation of fantasy display technology, due to its advantages of self-luminance, fast response, wide viewing angle, high definition, high luminance, high tolerance against bending, low energy consumption and the like.

At present, vacuum vapor deposition technique is a main procedure for preparing the OLED panel. The current major technical problems in the industry are how to improve the lamination fit between a mask and a deposition substrate and improve the effect of the vapor deposition.

### SUMMARY

The present disclosure provides a mask device, a vapor deposition device and a method for preparing the mask device, in order to improve the poor lamination fit between a mask and a substrate to be vapor-deposited.

In a first aspect, the present disclosure provides a mask device. The mask device includes a mask made of a ferromagnetic material. The mask includes: at least one deposition area in which deposition through-holes are defined and at least one non-deposition area comprising a transition area adjacent to the deposition area. Transition holes each having a volume less than a volume of the deposition through-hole are defined in the transition area, and the volume of the transition holes gradually decreases in a direction from the deposition area to the non-deposition area.

In a second aspect, the present disclosure provides a vapor deposition device, including the mask device according to the first aspect of the present disclosure.

In a third aspect, the present disclosure provides a method for preparing a mask device. The method of vapor deposition includes steps of: providing a master mask comprising at least one deposition area and at least one non-deposition area; and forming deposition through-holes in the deposition area and forming transition holes in the transition area, for forming a mask. A volume of the transition hole is less than a volume of the deposition through-hole, and the volume of the transition holes gradually decreases in a direction from the deposition area to the non-deposition area.

### BRIEF DESCRIPTION OF DRAWINGS

In order to clarify the technical solutions in the embodiments of the present disclosure or in the related art, the accompanying drawings necessary for describing the embodiments or the related art are briefly introduced as follows. It should be understood that the accompanying drawings described below illustrate some embodiments of the present disclosure.

FIG. 1 illustrates a schematic diagram of the principle of vapor deposition provided in an embodiment of the present disclosure;

FIG. 2 illustrates a first structural schematic diagram of a mask device provided in an embodiment of the present disclosure;

FIG. 3 illustrates a cross-sectional view along AA′ shown in FIG. 2;

FIG. 4 illustrates a first flow chart of a method for preparing a mask device provided in an embodiment of the present disclosure.

FIG. 5 illustrates a second structural schematic diagram of a mask device provided in an embodiment of the present disclosure;

FIG. 6 illustrates a third structural schematic diagram of a mask device provided in an embodiment of the present disclosure;

FIG. 7 illustrates a fourth structural schematic diagram of a mask device provided in an embodiment of the present disclosure;

FIG. 8 Illustrates a first cross-sectional view along BB′ shown in FIG. 7;

FIG. 9 Illustrates a second cross-sectional view along BB′ shown in FIG. 7;

FIG. 10 illustrates a second flow chart of a method for preparing a mask device provided in an embodiment of the present disclosure;

FIG. 11 illustrates a fifth structural schematic diagram of a mask device provided in an embodiment of the present disclosure;

FIG. 12 illustrates a cross-sectional view along CC′ shown in FIG. 11;

FIG. 13 illustrates a sixth structural schematic diagram of a mask device provided in an embodiment of the present disclosure;

FIG. 14 illustrates a cross-sectional view along DD′ shown in FIG. 13;

FIG. 15 illustrates a seventh structural schematic diagram of a mask device provided in an embodiment of the present disclosure;

FIG. 16 illustrates a cross-sectional view along EE′ shown in FIG. 15;

FIG. 17 illustrates a eighth structural schematic diagram of a mask device provided in an embodiment of the present disclosure;

FIG. 18 illustrates a structural schematic diagram of a vapor deposition device provided in an embodiment of the present disclosure.

### DESCRIPTION OF EMBODIMENTS

The technical terms in the embodiments of the present disclosure are merely used for the purpose of describing particular embodiments and are not intended to limit the present disclosure. The singular forms “a,” “an,” and “the” used in the embodiments of the disclosure and the appended claims also refer to the plural forms thereof, unless otherwise noted.

It should be understood that the term “and/or” is merely used herein to describe an associated relationship of objects, indicating three possible relationships. For example, “A and/or B” means three situations: only A is present, both A and B are present, and only B is present. In addition, the character “/” in the context generally means the objects are in an “or” relationship.

It should be understood that, although the technical terms first, second, etc. may be used to describe transition holes in the embodiments of the present disclosure, the transition holes should not be limited to these terms. These technical terms are only used to distinguish transition holes from one another. For example, a first transition hole can also be named as a second transition hole, and similarly, a second transition hole can also be named as a first transition hole, and similarly, a first transition sub-hole can also be named as a second transition sub-hole, without departing from the scope of the embodiments of the present disclosure.

It should be noted that, the terms such as “upper”, “lower”, “left” and “right” described in the embodiments of the present disclosure are used from the perspectives shown in the drawings and should not be understood as limitation to the embodiments of the present disclosure. In the context, it is to be understood that, when a structure is described as being “on” or “under” another structure, it not only can be directly formed “on” or “under” another structure, but also can be indirectly formed “on” or “under” another structure via an intermediate structure.

Before illustrating the technical solutions of the present disclosure, the principle and process of vapor deposition are briefly described as follows:

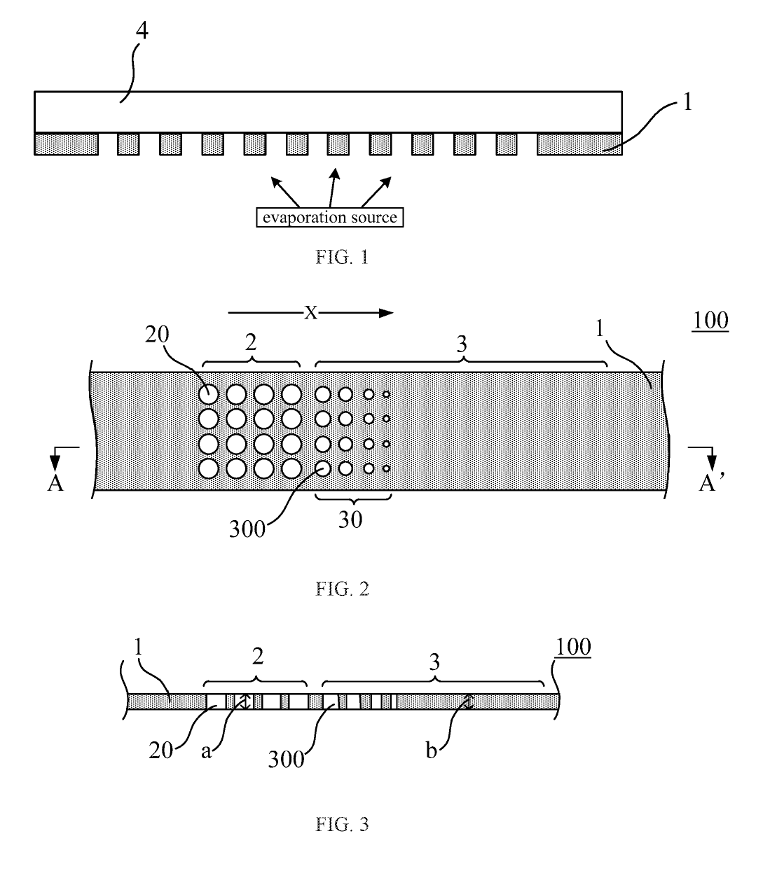

As shown in FIG. 1, which is a schematic diagram of the principle of vapor deposition provided in an embodiment of the present disclosure, vapor deposition on the substrate 4 to be deposited is mainly performed by an vapor deposition method (physical vapor deposition method), in which the surface of the (solid or liquid) evaporation source is vaporized into gaseous atoms and/or molecules, or is partially ionized into ions, the area not to be vapor-deposited is covered by a mask 1, the vaporized gaseous atoms or molecules are deposited on the area to be deposited on the surface of the substrate and a film is formed in a specific area on the surface of the substrate 4 to be vapor-deposited.

The vapor deposition on the substrate 4 to be vapor-deposited is usually performed in a vacuum chamber (not shown), in which the evaporation source is heated, and vaporized atoms, molecules or ions condense on the substrate 4 to be vapor-deposited with a lower temperature by passing through a deposition through-hole defined in the mask 1.

In practice, the process of vapor deposition has extremely high requirements on the flatness of the mask. However, the mask may deform under the effect of gravity, so that the flatness of the mask is negatively affected, which in turn negatively influences the effect of the vapor deposition.

In order to eliminate the influence of gravity on the flatness of the mask, net-tension technique is usually used, i.e., a certain pulling force is applied on the mask, making the mask in a tension state. Under the tension state, the two ends of the mask are fixed on a mask frame, and in the meantime, a magnetic plate arranged above the mask provides a magnetic force for balancing the gravity of the mask, reducing the influence of the gravity of the mask on the mask flatness.

However, the process of net tension leads to a problem of wrinkles in the mask, which can cause a poor lamination fit between the mask and the substrate, resulting in a problem of poor vapor deposition. In the related art, auxiliary holes are defined in a non-deposition area except an encapsulation area of the mask. The auxiliary holes aim to solve the problem of the wrinkles in the net-tension techniques, rather than for the vapor deposition. The auxiliary holes are typically either full-etched or half-etched with a great abrupt change in volume at the junction with the area outside the area with these auxiliary holes.

The technical solutions described above eliminate the influence of gravity on the flatness of the mask. However, due to the great abrupt change between the deposition through-holes in the deposition area and the encapsulation area (a portion of the non-deposition area) without the auxiliary holes or only with half-etched auxiliary holes, under the complex magnetic force, the poor lamination fit between the substrate to be vapor-deposited and the mask can be resulted from a repulsive magnetic force near the junction between the deposition area and the non-deposition area, thereby affecting the effect of vapor deposition. In one embodiment, with respect to the popular abnormal display arrangement at present, an abnormal display substrate is hardly to be arranged in a secure position (without the abrupt change) during the vapor deposition of the abnormal display substrate (substrate to be vapor-deposited), so that the poor lamination fit certainly occurs and affects the effect of vapor deposition.

For overcoming the problem of poor lamination fit caused by abrupt change and improving the effect of vapor deposition, the inventor provides the following technical solutions:

A mask device is provided in an embodiment of the present disclosure, as shown in FIG. 2 and FIG. 3. FIG. 2 illustrates a first structural schematic diagram of a mask device provided in an embodiment of the present disclosure, and FIG. 3 illustrates a cross-sectional view along AA′ shown in FIG. 2. The mask device 100 includes a mask 1 made of ferromagnetic material. The mask 1 includes at least one deposition area 2 and at least one non-deposition area 3. Deposition through-holes 20 are defined in the deposition area 2. The non-deposition area 3 includes a transition area 30 adjacent to the deposition area 2, transition holes 300 are defined in the transition area 30, the transition hole 300 has a volume less than a volume of the deposition through-hole 20, the volume of the transition holes 300 gradually decreases in a direction X from the deposition area 2 to the non-deposition area 3.

In the present embodiment, the volume of the transition hole is less than the volume of the deposition through-hole. It can be understood that, at the junction between the deposition area and the non-deposition area (transition area), the volume of the transition hole in the non-deposition area (transition area) adjacent to this junction is less than the volume of the deposition through-hole in the deposition area adjacent to this junction. In addition, the volume of the transition holes gradually decreases in the direction from the deposition area to the non-deposition area. In other words, a rate of volume change from the deposition through-holes to the transition holes is reduced as much as possible, and the repulsive force resulted from magnetic effect is also reduced, so that the abrupt change at the junction can be avoided, and the lamination fit between the substrate to be vapor-deposited and the mask as well as the effect of vapor deposition can be further improved. Further, in the present embodiment, since the abrupt change at the junction is avoided, no matter the substrate to be vapor-deposited is an abnormal display substrate or a rectangular display substrate, the problem of poor lamination fit will not occur, improving the effect of vapor deposition.

In a further embodiment, at the junction between the deposition area and the non-deposition area, the volume of the transition hole in the non-deposition area (transition area) adjacent to the junction can be slightly less than the volume of the deposition through-hole in the deposition area adjacent to the junction. In addition, the volume of the transition holes gradually decreases in the direction from the deposition area to the non-deposition area, and a volume difference between every two successive deposition through-holes is reduced as much as possible, so that the abrupt change at the junction can be minimized to the greatest extent.

Further, in one embodiment, the structure of the deposition through-hole in the deposition area is the same as the structure of the transition hole in the non-deposition area (transition area), and in the direction from the deposition area to the non-deposition area, only the volume of the transition hole gradually decreases, so that the repulsive force generated by the magnetic effect is reduced as much as possible to avoid the occurrence of the abrupt change. Therefore, the lamination fit and the effect of vapor deposition are improved.

It should be understood that, in the present embodiment, the transition holes are defined in the non-deposition area (transition area and the positions of the substrate to be vapor-deposited corresponding to the transition holes are not used for pixel display. Through-type deposition holes can be defined in a portion of the non-deposition area between the encapsulation area (the area may not be deposited with material) and the deposition area, and a series of patterns are vapor-deposited at a portion of the substrate to be vapor-deposited corresponding to said portion of the non-deposition area. These patterns are not used for pixel display. The size of the patterns vapor-deposited in the direction from the deposition area to the non-deposition area is gradually reduced. In the direction from the deposition area to the non-deposition area, no patterns are vapor deposited on the substrate in front of or at the beginning of the deposition area. In addition, the transition holes provided in the non-deposition area (transition area) are intended to reduce the abrupt change from the deposition area to the non-deposition area caused by etching, reduce the repulsive force generated by the magnetic force in the abrupt change area and thus the poor lamination fit between the substrate to be vapor-deposited and the mask caused by the repulsive force, and reduce the problems of poor vapor deposition caused by poor lamination fit. As an example, based on the orientation shown in FIG. 2, an area at the left side of the deposition area 2 is a non-deposition area, and an area at the right side of the deposition area also can be a non-deposition area. In addition, the present embodiment does not particularly limit the structure of the deposition through-hole, provided that the deposition through-holes are provided at corresponding positions on the mask.

In addition, the mask according to the present embodiment is suitable for any substrate to be vapor-deposited. Exemplarily, the deposition through-holes defined in the deposition area of the mask correspond to a light-emitting display area, When the substrate to be vapor-deposited is an OLED display substrate.

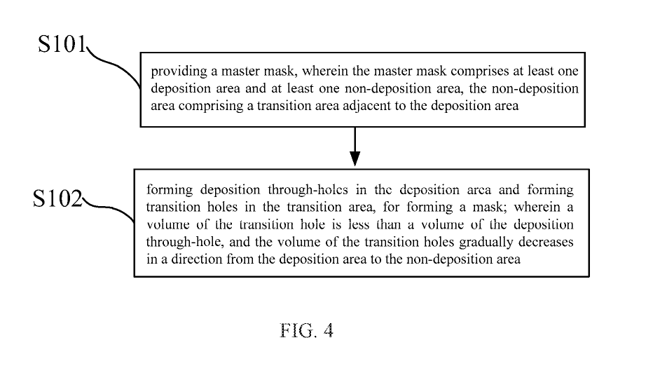

In combination with the above-mentioned structure of the mask device, the present embodiment provides a method for preparing a mask device, as shown in FIG. 4. FIG. 4 illustrates a first flow chart of the method for preparing a mask device.

S101: A master mask is provided, the master mask can be understood as an original model of the mask. The original model can be the mask itself or a mold used for preparing the mask, The master mask has at least one deposition area and at least one non-deposition area. The deposition area and the non-deposition area can be formed on the master mask by electroforming or wet etching.

S102: Deposition through-holes are formed in the deposition area and transition holes are formed in the transition area for forming a mask. The transition hole has a volume less than the volume of the deposition through-hole, and the volume of the transition holes gradually decreases in the direction from the deposition area to the non-deposition area.

The other structures of the mask device are described as follows.

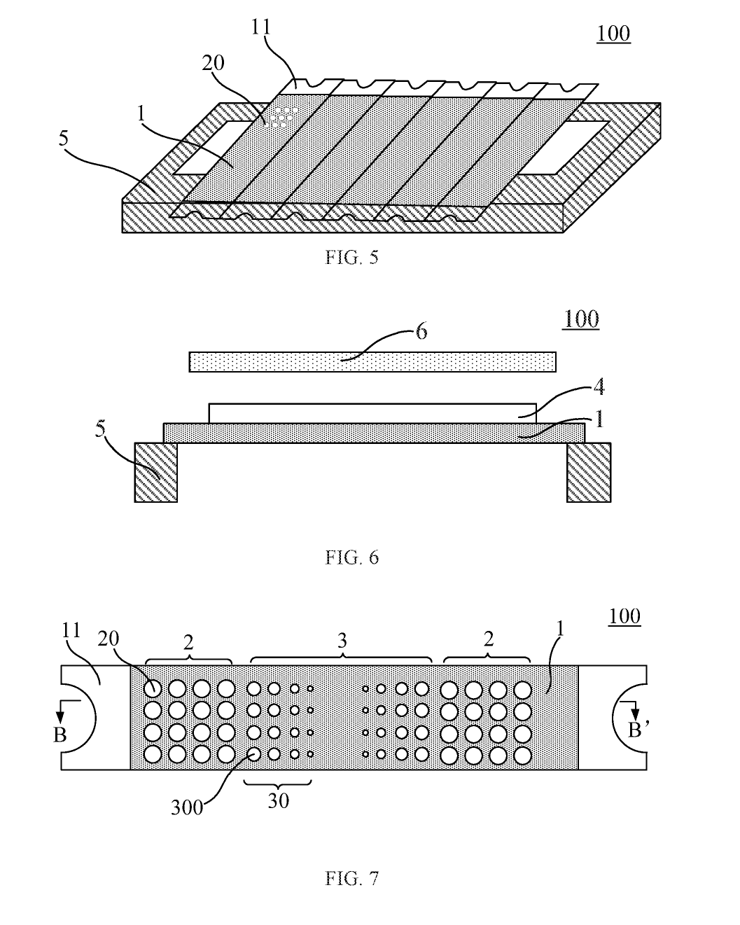

In one embodiment as shown in FIGS. 5 and 6, FIG. 5 illustrates a second structural schematic diagram of a mask device, FIG. 6 illustrates a third structural schematic diagram of a mask device. The mask device 100 further includes: a mask frame 5 for supporting the mask 1 which is fixed on the mask frame 5, a substrate 4 to be vapor-deposited, and a magnetic plate 6. The substrate 4 is provided on a first side of the mask 1 and in contact with the mask 1. In the present embodiment, based on the orientation shown in FIG. 6, the side of the mask 1 in contact with the substrate 4 to be vapor-deposited is named as the first side of the mask 1, the side of the mask 1 in contact with the mask frame 5 is called as a second side of the mask 1, and the first side and the second side are opposite to one another. The magnetic plate 6 is provided on a side of the substrate 4 to be vapor-deposited away from the mask 1, in order to facilitate the magnetic force generated by the magnetic plate 6 to balance the gravity of the mask 1.

Additionally, as shown in FIG. 7, which illustrates a fourth structural schematic diagram of the mask device provided in an embodiment of the present disclosure, the mask 1 can further include a clamping portion 11. In the net-tension process, the mask was drawn (stretched) by the clamping portion 11. The stretched mask 1 is welded onto the mask frame 5, and finally the redundant portion (redundant mask and clamping portion) is cut off. The mask according to this embodiment can be an integrated structure, or can be a discrete structure as shown in FIG. 5. In case of the discrete structure, the number of masks is not specifically limited in the embodiment. In addition, for example, as shown in FIG. 7, a plurality of deposition areas and a plurality of non-deposition areas can be defined on the mask. In the non-deposition areas, transition holes may be defined in the transition area, no transition hole may be defined in the areas except the transition area, and the non-deposition areas without the transition hole can be referred to as non-etching areas. This embodiment does not particularly limit the number of the deposition areas and non-deposition areas on the mask.

With reference to FIG. 6, the vapor deposition process according to this embodiment is briefly exemplified as below:

First, the mask 1 is fixed on the mask frame 5 before the vapor deposition. For example, the mask 1 can be welded onto the mask frame 5; then, the substrate 4 to be vapor-deposited 4 and the mask 1 are tightly laminated, and the magnetic plate 6 is placed at a suitable position so that the magnetic force of the magnetic plate 6 absorbs the mask 1 (mask is made of a ferromagnetic material); and then, the vapor deposition chamber is vacuumed to a predetermined degree of vacuum and the evaporation source (not shown) is opened for vapor deposition.

An embodiment is shown in FIGS. 3 and 8. FIG. 8 illustrates a first cross-sectional view along BB′ shown in FIG. 7 provided in the embodiment of the present disclosure. A thickness of the deposition area 2 of the mask 1 is a, and a thickness of the non-deposition area 3 of the mask 1 is b. As the surface density of the mask decreases in the direction from the deposition area to the non-deposition area, it is set that a≥b in order to reduce an abrupt change of the surface density from the deposition area to the non-deposition area and reduce the abrupt change caused by the magnetic force to improve the yield. From the perspective of the difficulty in manufacturing process, it is set that a=b.

It should be understood that, as an example shown in FIG. 3, the thickness of the non-deposition area of the mask is equal to the thickness of the deposition area, i.e., a=b. Or, as shown in FIG. 8, the thickness the non-deposition area of the mask is less than the thickness of the deposition area, i.e., b<a.

It should be understood that, in the present disclosure, the thickness of the non-etching area in the non-deposition area of the mask is less than or equal to the thickness of the deposition area of the mask, so that there is no increase of the thickness of the mask and no decrease of the size of the auxiliary holes in the direction from the deposition area to the non-deposition area. The reason is in that, although an integral stiffness of the mask can be increased due to thickness increase of the mask in the direction from the deposition area to the non-deposition area, the mass of the mask material in the transition area (equivalent to the surface density) increases. Therefore, a greater repulsive magnetic force is generated between the deposition area and the transition area, or a greater repulsive magnetic force is generated between a non-thickened portion and a thickened portion. The greater repulsive magnetic force seriously increases the lamination fit difficulty of the mask, eventually resulting in that the mask may not be laminated well to the glass substrate under the influence of the repulsive magnetic force, causing the problem of poor vapor deposition. In the embodiment of the present disclosure, the thickness of the non-deposition area of the mask is less than or equal to the thickness of the deposition area of the mask, mass difference between the non-deposition area and the deposition area can be reduced, and thus the risk of abrupt change at the junction decreases. Therefore, the repulse magnetic force is reduced, the repulsive magnetic force applied by the magnetic plate on the mask around the area where the abrupt change occurs can be reduced, and the lamination fit between the substrate to be vapor-deposited and the mask is improved, thereby improving the effect of vapor deposition.

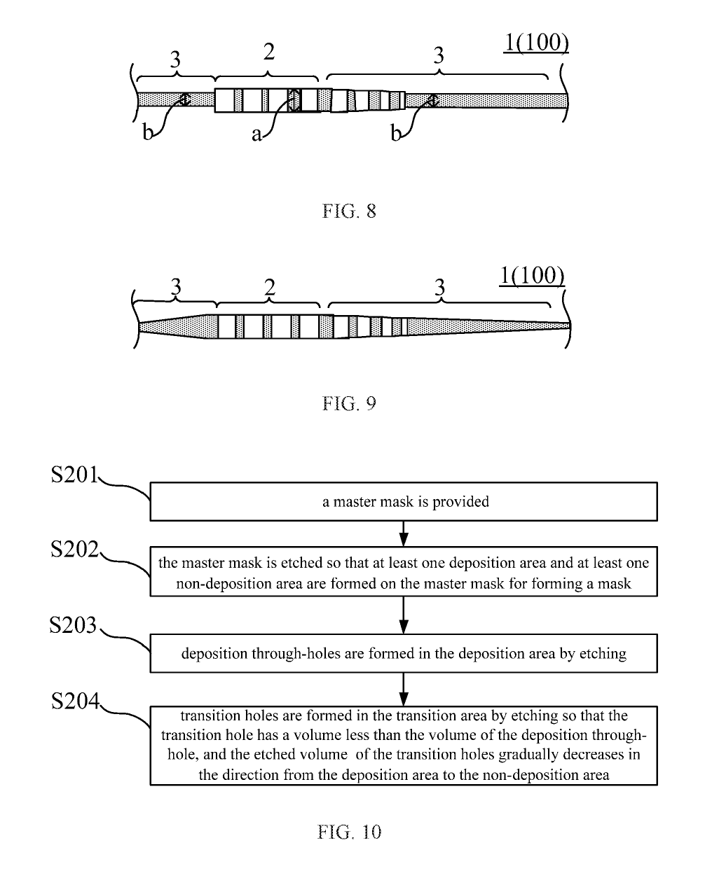

Further, with reference to the embodiment described above, the volume of the transition holes in the transition area gradually decreases, as shown in FIG. 9. FIG. 9 illustrates a cross-sectional view along BB′ shown in FIG. 7. The thickness of the non-deposition area gradually decreases in the direction from the deposition area to the non-deposition area, so that the surface density of the non-deposition area without transition holes is much closer to the surface density of the non-deposition area with transition holes. Therefore, the difference in surface density between the deposition area and the non-deposition area is reduced, so that the abrupt change at the junction decreases, improving the lamination fit between the substrate to be vapor-deposited and the mask and the effect of vapor deposition.

In order to reduce the abrupt change at the junction between the deposition area and the non-deposition area and reduce the repulsive magnetic force at the junction, the inventor has made improvements to the mask (mask device). Before introducing the structure of the mask device, a method for preparing the mask device is firstly introduced. In the method, the mask (mask device) is prepared based on the wet etching principles (described in details as follows).

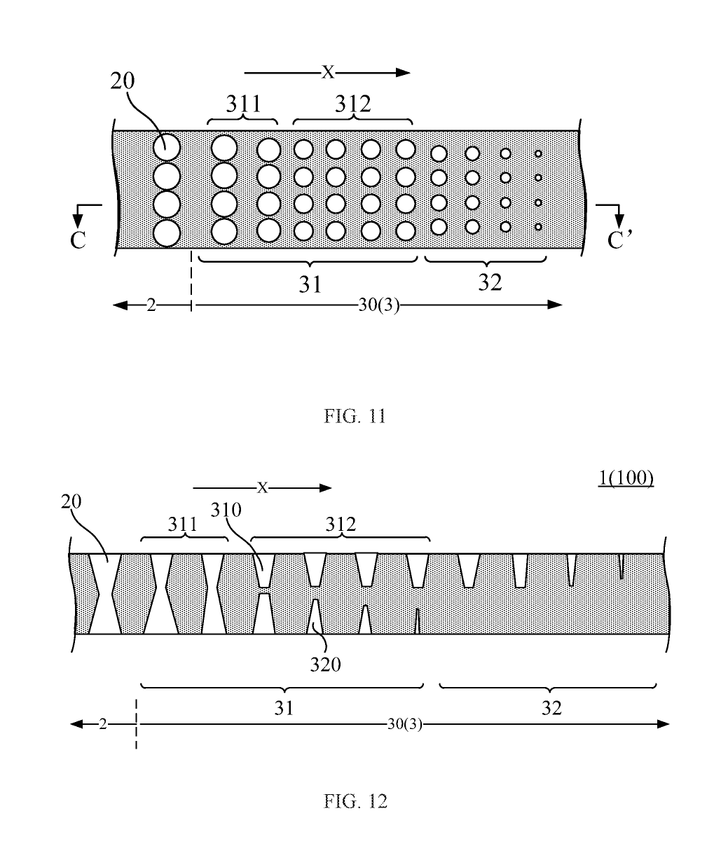

FIG. 10 illustrates a second flow chart of a method for preparing a mask device provided in an embodiment of the present disclosure. The method for preparing the mask device includes the following steps.

S201: a master mask is provided.

S202: the master mask is etched so that at least one deposition area and at least one non-deposition area are formed on the master mask for forming a mask.

S203: deposition through-holes are formed in the deposition area by etching.

S204: transition holes are formed in the transition area by etching so that the transition hole has a volume less than the volume of the deposition through-hole, and the etched volume of the transition holes gradually decreases in the direction from the deposition area to the non-deposition area.

In this embodiment, the master mask can be understood as the mask itself, and corresponding positions on the mask are corroded with a corrosion solution to obtain a mask having the same structure as that described in the above embodiment.

In some embodiments, the structure of the mask is as follows:

A first type is shown in FIG. 11 and FIG. 12. FIG. 11 illustrates a fifth structural schematic diagram of a mask device provided in an embodiment of the present disclosure, and FIG. 12 illustrates a cross-sectional view along CC′ shown in FIG. 11. In the direction X from the deposition area 2 to the non-deposition area 3, the transition area 30 sequentially includes a first transition area 31 and a second transition area 32.

The transition holes 300 include first transition holes 310 and second transition holes 320, the first transition holes 310 are arranged at the first side of the mask 1, while the second transition holes 320 are arranged at the second side of the mask 1, and the first side and the second side are opposite to one another.

In the first transition area 31, in the direction from the deposition area 2 to the non-deposition area 3, the volume of the first transition holes 310 remains unchanged, while the volume of the second transition holes 320 gradually decreases.

In the second transition region 32, there is no second transition hole 320, and the volume of the first transition holes 310 gradually decreases in the direction from the deposition area 2 to the non-deposition area 3.

In combination with the structure of the mask device shown in FIG. 12, a method for preparing the mask device is provided as follows. In the direction from the deposition area to the non-deposition area, the etched volume of the first transition holes remains unchanged while the etched volume of the second transition holes gradually decreases in the first transition area, and the etched volume of the first transition holes gradually decreases in the second transition area.

Further, referring to FIG. 12, in the direction from the deposition area 2 to the non-deposition area 3, the first transition area 31 sequentially includes a first transition sub-area 311 and a second transition sub-area 312. In the first transition sub-area 311, the first transition hole 310 and the second transition hole 320 are in communication with one another. In the second transition sub-area 312, the first transition holes 310 and the second transition holes 320 are not in communication with one another, and the depth of the second transition holes 320 in the direction perpendicular to the plane of the mask 1 gradually decreases in the direction from the deposition area 2 to the non-deposition area 3.

In the present embodiment, the first transition holes and the second transition holes are not in communication with one another in the second transition sub-area, i.e., both the first transition hole and the second transition hole have a semi-hole structure.

It should be understood that, in the present disclosure, the portion of the non-deposition area of the mask close to the deposition area is generally provided with auxiliary holes (non-deposition holes). These non-deposition holes are usually non-through auxiliary holes. Therefore, the adverse effects on the encapsulation caused by the auxiliary holes in the non-deposition area of the mask can be avoided. The reason is in that, the encapsulation area may not be with the material, and the material vapor-deposited on the encapsulation area can lead to a failure of the encapsulation. If a shield plate is used to shield the area to be encapsulated, the shield plate may not completely shield all of the auxiliary holes in the encapsulation area due to a design issue (for example, the display panel is a non-rectangular display panel, i.e., an abnormal display panel). If the abnormal display panel is provided with through-type auxiliary hole, the material may be vapor-deposited on the encapsulation area, leading to the failure of the encapsulation.

However, without the auxiliary holes, wrinkles can be easily formed due to net-tension, which is the difficulty in the abnormal display panel. In the present embodiment, the non-through auxiliary holes (transition holes) with gradual sizes are helpful to the encapsulation of the abnormal display panel.

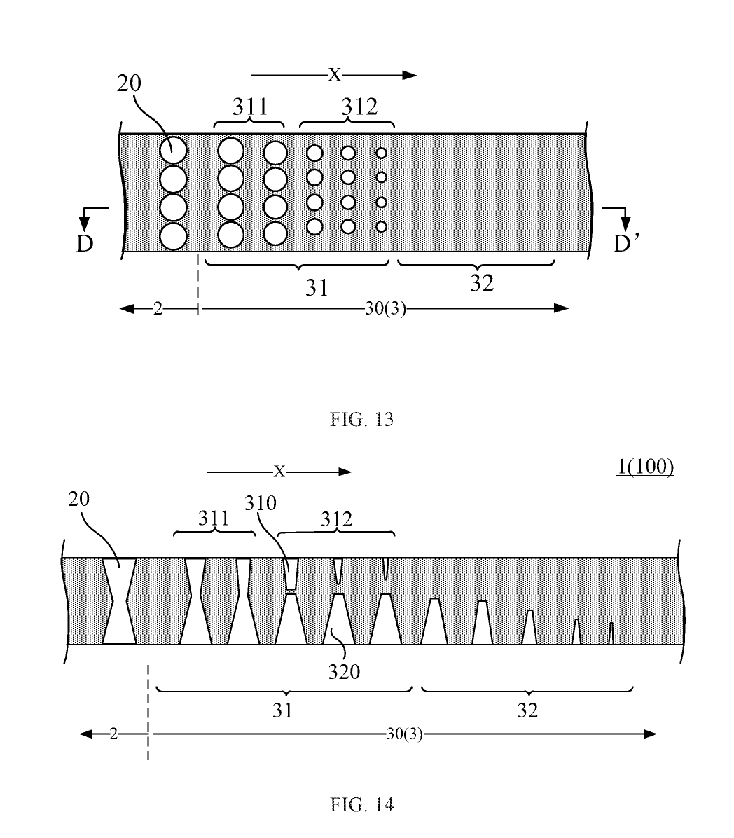

A second type is shown in FIG. 13 and FIG. 14. FIG. 13 illustrates a sixth structural schematic diagram of a mask device provided in an embodiment of the present disclosure, and FIG. 14 illustrates a cross-sectional view along DD′ shown in FIG. 13. In the direction from the deposition area 2 to the non-deposition area 3, the transition area 30 sequentially includes a first transition area 31 and a second transition area 32, The transition holes 300 include first transition holes 310 and second transition holes 320, the first transition holes 310 are arranged at the first side of the mask 1, the second transition holes 320 are arranged at the second side of the mask 1, and the first side and the second side are opposite to one another. In the present embodiment, the first side of the mask 1 is the side in contact with the substrate to be vapor-deposited, and the second side of the mask 1 is the side away from the substrate to be vapor-deposited. In the first transition area 31, in the direction from the deposition area 2 to the non-deposition area 3, the volume of the first transition holes 310 gradually decreases, while the volume of the second transition holes 320 remains unchanged. In the second transition area 32, no first transition hole 310 is defined, and the volume of the second transition holes 320 gradually decreases in the direction from the deposition area 2 to the non-deposition area 3.

In combination with the structure of the mask device shown in FIG. 14, a method for preparing the mask device is provided as follows.

In the first transition area, in the direction from the deposition area to the non-deposition area, the etched volume of the first transition holes gradually decreases, while the etched volume of the second transition holes remains unchanged. In the second transition area, the etched volume of the second transition holes gradually decreases.

Further, referring to FIG. 14, in the direction from the deposition area 2 to the non-deposition area 3, the first transition area 31 sequentially includes a first transition sub-area 311 and a second transition sub-area 312.

In the first transition sub-area 311, the first transition holes 310 and the second transition holes 320 are in communication with one another.

In the second transition sub-area 312, the first transition holes 310 and the second transition holes 320 are not in communication with one another, and the depth of the first transition holes 310 in the direction perpendicular to the plane of the mask 1 gradually decreases in the direction from the deposition area 2 to the non-deposition area 3.

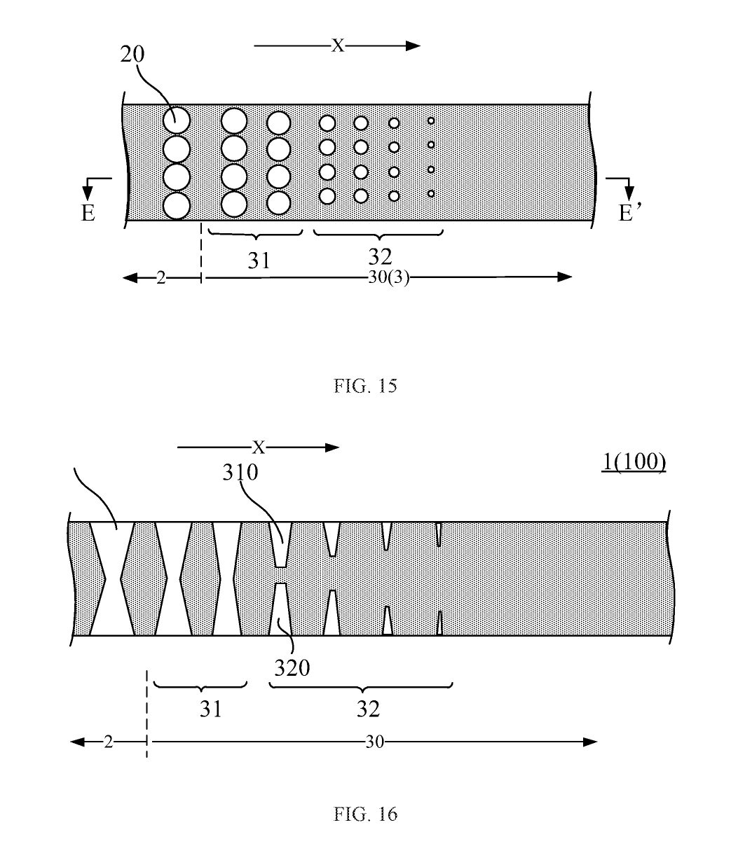

A third type is shown in FIG. 15 and FIG. 16. FIG. 15 illustrates a seventh structural schematic diagram of a mask device provided in an embodiment of the present disclosure, and FIG. 16 illustrates a cross-sectional view along EE′ shown in FIG. 15. The transition holes 300 include first transition holes 310 and second transition holes 320, The first transition holes 310 are arranged at the first side of the mask 1, the second transition holes 320 are arranged at the second side of the mask 1, and the first side and the second side are opposite to one another. In the present embodiment, the first side of the mask 1 is the side in contact with the substrate to be vapor-deposited, and the second side of the mask 1 is the side away from the substrate to be vapor-deposited.

In the transition area 30, in the direction from the deposition area 2 to the non-deposition area 3, the volume of the first transition holes 310 and the volume of the second transition holes 320 gradually decrease in the meantime.

In combination with the structure of the mask device shown in FIG. 16, a method for preparing the mask device is provided as follows.

In the transition area, in the direction from the deposition area to the non-deposition area, the etched volume of the first transition holes gradually decreases, and the etched volume of the second transition holes also gradually decreases.

Further, referring to FIG. 16, the transition area 30 includes a first transition area 31 and a second transition area 32.

In the first transition area 31, the first transition holes 310 and the second transition holes 320 are in communication with one another.

In the second transition area 32, in the direction from the deposition area 2 to the non-deposition area 3, the depth of the first transition holes 310 in the direction perpendicular to the plane of the mask 1 gradually decreases, and the depth of the second transition holes 320 in the direction perpendicular to the plane of the mask also gradually decreases.

The transition holes of the above-mentioned three types of structures are all formed by wet etching. The purpose of etching can be achieved by adjusting the amount of acid solution used in the areas to be etched.

In an embodiment, as shown in FIGS. 12, 14 and 16, the cross sections of the first transition holes 310 and the second transition holes 320 can all have a trapezoidal shape in a direction from the first side to the second side.

Or, the first transition holes 310 and the second transition holes 320 all have rectangular cross sections; or the first transition holes 310 and the second transition holes 320 all have semi-elliptical cross sections.

Take the structure of the mask device shown in FIG. 15 for example. An orthographic projection of an opening of the first transition hole 310 close to the first side on the plane of the mask 1 covers an orthographic projection of an opening of the first transition hole 310 away from the first side on the plane of the mask 1; an orthographic projection of an opening of the second transition hole 320 close to the second side on the plane of the mask 1 covers an orthographic projection of an opening of the second transition hole 320 away from the second side on the plane of the mask 1. That is, based on the orientation shown in FIG. 15, the opening of the trapezoidal first transition hole 310 at the first side has a width (the width of the long side of the trapezoid) greater than the width of the bottom opening of the first transition hole 310 (the width of the short side of the trapezoid). The widths of the second transition hole 320 are exactly the opposite case of the first transition hole 310, which is not repeated herein. No matter the first transition holes and the second transition holes are trapezoidal, rectangular or semi-elliptical, they can be prepared by the wet etching method.

It should be noted that, the first transition holes and the second transition holes structured above are merely exemplary. In fact, it is applicable provided that the volume of the first transition holes as well as the volume of the second transition holes gradually decreases in the direction from the deposition area to the non-deposition area.

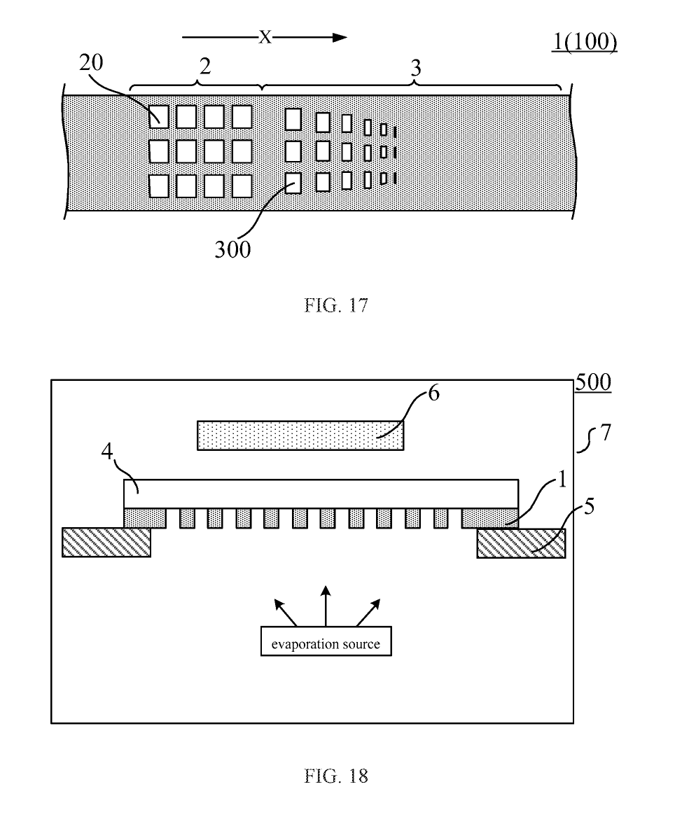

FIG. 17 illustrates an eighth schematic structural diagram of a mask device provided in an embodiment of the present disclosure. In a direction perpendicular to the plane of the mask 1, the cross sections of the transition holes 300 can also be rectangular, and the volume of the transition holes 300 gradually decreases in the direction X from the deposition area 2 to the non-deposition area 3.

In combination with the structure of the mask device shown in FIG. 17, the present embodiment provides a method for preparing a mask device. In this method, the electroforming method (specific principle is described as below) is suitable to prepare the mask. The method includes forming a mask with a master mask by electroforming.

In the present embodiment, the master mask can be understood as an original model of the mask, i.e., a mold for preparing the mask. On the mold, the volume of the transition holes gradually decreases in the direction from the deposition area to the non-deposition area, so that an electroformed mask which is the same as the mold can be obtained.

The principle of electroforming is briefly introduced as follows.

The electroforming method is a method for plating a layer of metal on a conductor based on the principle of electrolysis. The electroforming method facilitates the production of display screens with high PPI (high pixel density), such as VR (virtual reality) display. The mold is set as a cathode, cations in the electrolyte solution are deposited on the mold by electrolysis, and demolding is performed, forming a mask with a same structure as the mold.

An embodiment of the present disclosure provides a vapor deposition device. The structural schematic diagram of the vapor deposition device provided in the embodiment of the present disclosure is illustrated in FIG. 18. The vapor deposition device 500 includes the mask device 1 according to any of the embodiments described above, and the vapor deposition device further includes a vapor deposition chamber 7.

As the vapor deposition device includes the mask device, the vapor deposition device can also solve the problem of abrupt change at the junction between the deposition area and the non-deposition area. In the vapor deposition device, the volume of the transition hole is less than the volume of the deposition through-hole. It should be understood that, at the junction between the deposition area and the non-deposition area (transition area), the volume of the transition hole in the non-deposition area (transition area) adjacent to this junction is less than the volume of the deposition through-hole in the deposition area adjacent to this junction. In addition, the volume of the transition holes gradually decreases in the direction from the deposition area to the non-deposition area. In other words, the volume change from the deposition through-holes to the transition holes is reduced as much as possible, so that the abrupt change at the junction is reduced and the repulsive force generated by the magnetic effect is also reduced. Therefore, the lamination fit between the substrate to be vapor-deposited and the mask as well as the effect of vapor deposition is improved.

Finally, it should be noted that, the embodiments described above are merely intended for illustrating the technical solutions of the present disclosure, rather than limiting the present disclosure. Even the present disclosure is described in details with reference to the embodiments described above.

What is claimed is:

1. A mask device, comprising:
a mask made of a ferromagnetic material, the mask comprising:
a deposition area, in which deposition through-holes are defined; and
a non-deposition area, comprising a transition area adjacent to the deposition area, wherein transition holes each having a volume less than a volume of the deposition through-hole defined in the transition area, and the volume of the transition holes gradually decreases in a direction from the deposition area to the non-deposition area.

2. The mask device according to claim 1, wherein a thickness of the deposition area of the mask is a, a thickness of the non-deposition area of the mask is b, and a≥b.

3. The mask device according to claim 1, wherein the transition holes comprise first transition holes and second transition holes, the first transition holes are arranged at a first side of the mask, and the second transition holes are arranged at a second side of the mask, wherein the first side and the second side are opposite to one another.

4. The mask device according to claim 3, wherein the transition area comprises a first transition area and a second transition area in the direction from the deposition area to the non-deposition area, wherein
in the first transition area, in the direction from the deposition area to the non-deposition area, a volume of the first transition holes remains unchanged and a volume of the second transition holes gradually decreases; and
in the second transition area, none of the second transition holes is defined and the volume of the first transition holes gradually decreases in the direction from the deposition area to the non-deposition area.

5. The mask device according to claim 4, wherein the first transition area comprises a first transition sub-area and a second transition sub-area in the direction from the deposition area to the non-deposition area; wherein
in the first transition sub-area, the first transition holes and the second transition holes are in communication with one another; and
in the second transition sub-area, the first transition holes and the second transition holes are not in communication with one another, and a depth of the second transition holes in a direction perpendicular to a plane of the mask gradually decreases in the direction from the deposition area to the non-deposition area.

6. The mask device according to claim 3, wherein the transition area comprises a first transition area and a second transition area in the direction from the deposition area to the non-deposition area, wherein
in the first transition area, in the direction from the deposition area to the non-deposition area, a volume of the first transition holes gradually decreases and a volume of the second transition holes remains unchanged; and
in the second transition area, none of the first transition holes is defined and the volume of the second transition holes gradually decreases in the direction from the deposition area to the non-deposition area.

7. The mask device according to claim 6, wherein the first transition area comprises a first transition sub-area and a second transition sub-area in the direction from the deposition area to the non-deposition area; wherein
in the first transition sub-area, the first transition holes and the second transition holes are in communication with one another; and
in the second transition sub-area, the first transition holes and the second transition holes are not in communication with one another, and a depth of the first transition holes in a direction perpendicular to the plane of the mask gradually decreases in the direction from the deposition area to the non-deposition area.

8. The mask device according to claim 3, wherein in the transition area, in the direction from the deposition area to the non-deposition area, both a volume of the first transition holes and a volume of the second transition holes gradually decrease.

9. The mask device according to claim 8, wherein the transition area comprises a first transition area and a second transition area, wherein in the first transition area, the first transition holes and the second transition holes are in communication with one another; and
in the second transition area, in the direction from the deposition area to the non-deposition area, a depth of the first transition holes in a direction perpendicular to a plane of the mask gradually decreases, and a depth of the second transition holes in the direction perpendicular to the plane of the mask gradually decreases.

10. The mask device according to claim 3, wherein cross sections of the first transition holes and the second transition holes in a direction from the first side to the second side are trapezoidal, semi-elliptical, or rectangular;
an orthographic projection of an opening of the first transition hole close to the first side on a plane of the mask covers an orthographic projection of an opening of the first transition hole away from the first side on the plane of the mask; and
an orthographic projection of an opening of the second transition hole close to the second side on the plane of the mask covers an orthographic projection of an opening of the second transition hole away from the second side on the plane of the mask.

11. The mask device according to claim 1, wherein cross sections of the transition holes in a direction perpendicular to a plane of the mask are rectangular.

12. The mask device according to claim 1, further comprising:
a mask frame, wherein the mask is fixed on the mask frame.

13. The mask device according to claim 1, further comprising:
a substrate to be vapor-deposited, wherein the substrate to be vapor-deposited is arranged on a first side of the mask and in contact with the mask; and
a magnetic plate arranged on a side of the substrate to be vapor-deposited away from the mask.

14. A vapor deposition device, comprising:
a mask device, wherein the mask device comprises a mask made of a ferromagnetic material, wherein the mask comprises:
a deposition area, in which deposition through-holes are defined; and
a non-deposition area, comprising a transition area adjacent to the deposition area, wherein transition holes each having a volume less than a volume of the deposition through-hole defined in the transition area, and the volume of the transition holes gradually decreases in a direction from the deposition area to the non-deposition area.

15. A method for preparing a mask device, comprising:
providing a master mask, wherein the master mask comprises a deposition area and a non-deposition area, the non-deposition area comprising a transition area adjacent to the deposition area; and
forming deposition through-holes in the deposition area and forming transition holes in the transition area, for forming a mask; wherein a volume of the transition hole is less than a volume of the deposition through-hole, and the volume of the transition holes gradually decreases in a direction from the deposition area to the non-deposition area.

16. The method for preparing a mask device according to claim 15, wherein the method of preparing a mask device comprises:
providing the master mask;
etching the master mask to form a deposition area and a non-deposition area on the master mask, for forming a mask;
forming deposition through-holes in the deposition area by etching; and
forming transition holes in the transition area by etching, wherein the volume of the transition hole is less than the volume of the deposition through-hole, and an etched volume of the transition holes gradually decreases in the direction from the deposition area to the non-deposition area.

17. The method for preparing a mask device according to claim 16, wherein the transition area comprises a first transition area and a second transition area in the direction from the deposition area to the non-deposition area,
the transition holes comprise first transition holes and second transition holes, the first transition holes are arranged at a first side of the mask, and the second transition holes are arranged at a second side of the mask, wherein the first side and the second side are opposite to one another; wherein
in the first transition area, in the direction from the deposition area to the non-deposition area, a volume of the first transition holes remains unchanged, and a volume of the second transition holes gradually decreases; and
in the second transition area, none of the second transition holes is defined, and the volume of the first transition holes gradually decreases in the direction from the deposition area to the non-deposition area;
wherein in the direction from the deposition area to the non-deposition area, an etched volume of the first transition holes in the first transition area remains unchanged, an etched volume of the second transition holes in the first transition area gradually decreases, and an etched volume of the first transition holes in the second transition area gradually decreases.

18. The method for preparing a mask device according to claim 16, wherein the transition area comprises a first transition area and a second transition area in the direction from the deposition area to the non-deposition area,
the transition holes comprise first transition holes and second transition holes, the first transition holes are arranged at a first side of the mask, and the second transition holes are arranged at a second side of the mask, wherein the first side and the second side are opposite to one another; wherein
in the first transition area, in the direction from the deposition area to the non-deposition area, a volume of the first transition holes gradually decreases, and a volume of the second transition holes remains unchanged; and
in the second transition area, none of the first transition holes is defined, and the volume of the second transition holes gradually decreases in the direction from the deposition area to the non-deposition area;
wherein in the direction from the deposition area to the non-deposition area, an etched volume of the first transition holes in the first transition area gradually decreases, an etched volume of the second transition holes in the first transition area remains unchanged, and an etched volume of the second transition holes in the second transition area gradually decreases.

19. The method for preparing a mask device according to claim 16, wherein the transition holes comprise first transition holes and second transition holes, the first transition holes are arranged at a first side of the mask, and the second transition holes are arranged at a second side of the mask, wherein the first side and the second side are opposite to one another; and
in the transition area, in the direction from the deposition area to the non-deposition area, both the volume of the first transition holes and the volume of the second transition holes gradually decrease; wherein
in the transition area, in the direction from the deposition area to the non-deposition area, the etched volume of the first transition holes gradually decreases, and the etched volume of the second transition holes gradually decreases.

20. The method for preparing a mask device according to claim 15, wherein the mask is formed with a master mask by electroforming.
